(19) United States
(12) Patent Application Publication
(10) Pub. No.: US 2007/0249071 A1
(43) Pub. Date: Oct. 25, 2007

(54) Neural Network Methods and Apparatuses for Monitoring Substrate Processing

(76) Inventors: Lei Lian, Santa Clara, CA (US); Vivien Chang, Sunnyvale, CA (US); Matthew Fenton Davis, Brookdale, CA (US); Quentin E. Walker, Palo Alto, CA (US)

Correspondence Address: PATTERSON & SHERIDAN, LLP, 3040 POST OAK BOULEVARD, SUITE 1500, HOUSTON, TX, 77056, US

(21) Appl. No.: 11/379,775

(22) Filed: Apr. 21, 2006

(51) Int. Cl. H01L 21/66; G01B 15/00

(52) U.S. Cl. 438/16; 702/155

(57) ABSTRACT

Aspects of the present invention include methods and apparatuses that may be used for monitoring substrate processing systems. One embodiment may provide an apparatus for obtaining in-situ data regarding processing of a substrate in a substrate processing chamber, comprising a data collecting assembly for acquiring training data related to a substrate disposed in a processing chamber, an electromagnetic radiation source, at least one in-situ metrology module to provide measurement data, and a computer, wherein the computer includes a neural network software, wherein the neural network software is adapted to model a relationship between the plurality of the training and other data related to substrate processing.

### BACKGROUND OF THE INVENTION

1. Field of the Invention

The present invention relates generally to methods and apparatuses for use in substrate processing. More specifically, the present invention relates to neural network monitoring methods and apparatuses for use in substrate processing, such as an etch process, deposition process, or other processes.

2. Description of the Related Art

Integrated circuits have evolved into complex devices that can include millions of components (e.g., transistors, capacitors, resistors, and the like) on a single chip. The evolution of chip designs continually requires faster circuitry and greater circuit density. The demands for greater circuit density necessitate a reduction in the dimensions of the integrated circuit components. The minimal dimensions of features of such devices are commonly referred to in the art as critical dimensions. The critical dimensions generally include the minimal widths of the features, such as lines, columns, openings, spaces between the lines, and the like.

As these critical dimensions shrink, accurate measurement and process control becomes more difficult. For example, one problem associated with a conventional plasma etch process used in the manufacture of integrated circuits is the lack of an ability to accurately monitor the formation of small features on the substrate and thereby accurately monitoring the endpoint for the etch process and measuring etch depths. U.S. Pat. No. 6,413,867 discloses a neural net pattern matching technique. Some problems that are associated with this technique may include difficulty of handling changes in the process regime and meeting different depth requirements.

Therefore, there is a need in the art for an improved method and apparatus for substrate monitoring and process control during the manufacture of integrated circuits.

### SUMMARY OF THE INVENTION

One embodiment of the present invention provides a method for monitoring film thickness of a substrate in a substrate processing system, comprising monitoring a first set of reflected electromagnetic radiation from an electromagnetic radiation source during processing of a first set of one or more substrates, associating the first set of reflected electromagnetic radiation to a film thickness profile of the first set of one or more substrates to form a first set of training data, monitoring a second set of reflected electromagnetic radiation data from the electromagnetic radiation source during processing of a second set of one or more substrates, and using the first set of training data to predict a film thickness profile of the second set of one or more substrates during processing of the second set of one or more substrates.

Another embodiment of the present invention provides an apparatus for obtaining in-situ data regarding processing of a substrate in a substrate processing chamber, comprising a data collecting assembly for acquiring training data related to a substrate disposed in a processing chamber, an electromagnetic radiation source, at least one in-situ metrology module to provide measurement data, and a computer, wherein the computer includes a neural network software, wherein the neural network software is adapted to model a relationship between the plurality of the training and other data related to substrate processing.

Another embodiment of the present invention provides a method for monitoring an etch depth profile of a substrate feature in a substrate processing system, comprising monitoring a first set of reflected electromagnetic radiation from an electromagnetic radiation source during processing of a first set of one or more substrates, associating the first set of reflected electromagnetic radiation to an etch depth profile of the first set of one or more substrates to form a first set of training data, wherein the associating the first set of reflected electromagnetic radiation is perform by neural network software, monitoring a second set of reflected electromagnetic radiation from the electromagnetic radiation source during processing of a second set of one or more substrates, and using the first set of training data to predict an etch depth of the second set of one or more substrates during processing of the second set of one or more substrates.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an exemplary schematic diagram of a processing system having one embodiment of the present invention;

FIG. 2 illustrates a multilayer perceptron network according to an embodiment of the present invention;

FIG. 3 illustrates a series of graphs showing changes in the spectral intensity of radiation reflected from a substrate during an etching process;

FIG. 4 illustrates a flow diagram of a method according to an embodiment of the present invention; and

FIGS. 5A, 5B, and 5C illustrate a series of schematic, cross-sectional views of a substrate having an etched material layer.

### DETAILED DESCRIPTION

Embodiments of the present invention provide methods and apparatuses that may be utilized to perform spectral analysis to monitor a process for fabricating integrated circuit devices on semiconductor substrates (e.g., silicon substrates, silicon on insulator (SOI) substrates, and the like), flat panel displays, solar panels, or other electronic devices. For example, in one embodiment, a method may provide process control by utilizing substrate state information derived from a reflectance signal collected at a designated area of a substrate under process and other related data, in combination, as training data, to train a neural network. The method uses related measurement data of structures at pre-etch, during etch, and post-etch (i.e., substrate state information) stages of a processing step to train a neural network (for example, a multilayer perceptron network) in order to adjust process time and control the operational status of a substrate processing equipment. For example, the method may be used to make improved real time etch depth predictions during an etch process. Data collection may be performed in-situ using a dynamic optical measuring tool capable of taking measurements at designated locations on a substrate, or it may be performed ex-situ; alternatively, it may be performed both in-situ and ex-situ for training the neural network to generate a working model. In this way, the system may dynamically estimate the etch depth (e.g., etch depth of a feature on a substrate) with high accuracy and high computational speed based on a series of measured optical signal intensities, film thicknesses and/or any other physical parameters by utilizing a neural network.

While the following description of the system is described with reference to a plasma processing chamber, the same techniques may be applied to other applications and systems where material thickness (i.e., film thickness), deposition layer thickness and other physical parameters are measured. For example, systems such as physical vapor deposition (PVD), chemical vapor deposition (CVD), plasma enhanced chemical vapor deposition (PECVD) and other substrate processing systems may benefit from the present invention.

Although some embodiments of the substrate processing system 100 are described with reference to a multiple perceptron network; it is contemplated that other types of neural networks may be utilized by the present invention.

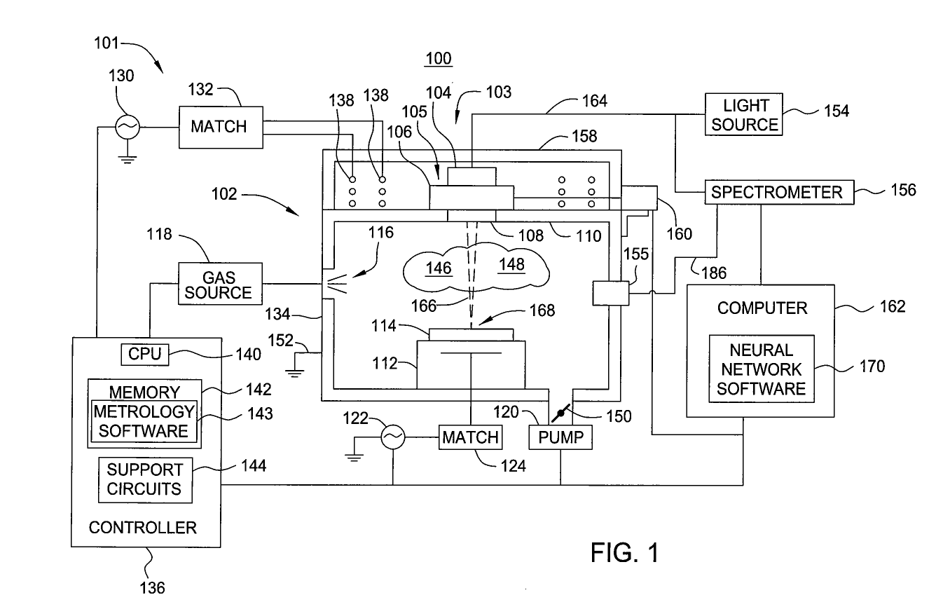

FIG. 1 depicts a schematic diagram of one illustrative embodiment of a substrate processing system 100 for fabricating integrated devices suitable for use with the present invention. The system 100 generally includes a plasma processing chamber, such as an etch reactor module 101 having a dynamic in-situ optical measuring tool 103. One illustrative embodiment of an etch reactor module 101 that can be used to perform the steps of the present invention is a Decoupled Plasma Source (DPS®) II etch reactor, available from Applied Materials, Inc. of Santa Clara, Calif. The DPS® II reactor is generally used as a processing module of a larger processing system, such as the TRANSFORMA™ system or a CENTURA® system, both of which are available from Applied Materials, of Santa Clara, Calif.

In one embodiment, the reactor module 101 comprises a process chamber 102, a plasma power source 130, a biasing power source 122, and a controller 136. The process chamber 102 comprises a substrate support pedestal 112 within a body (wall) 134, which may be made of a conductive material. The chamber 102 is supplied with a dielectric ceiling 110. In the depicted embodiment, the ceiling 110 is substantially flat. Other embodiments of the chamber 102 may have other types of ceilings, e.g., a curved or domed ceiling. A lid 158 may be additionally provided to house and protect additional components of the reactor 101 as well as form a shield for RF radiation. Above the ceiling 110 and within the lid 158 is disposed an antenna comprising at least one inductive coil element 138 (shown in FIG. 1 as two coil elements 138). The inductive coil element 138 is coupled through a first matching network 132 to the plasma power source 130. The plasma source 130 typically is capable of producing a power signal at a fixed or tunable frequency in a range from about 50 kHz to about 13.56 MHz.

The support pedestal (cathode) 112 is coupled through a second matching network 124 to the biasing power source 122. The biasing source 122 generally is a source of a power signal at a fixed or tunable frequency of approximately 50 kHz to about 13.56 MHz that is capable of producing either continuous or pulsed power. In other embodiments, the source 122 may be a DC or pulsed DC source.

The controller 136 includes a central processing unit (CPU) 140, a memory 142, and support circuits 144 for the CPU 140 and facilitates control of the components of the DPS II etch process chamber 102 and, as such, of the etch process, as discussed below in further detail. The controller 136 may be one of any form of general-purpose computer processors that can be used in an industrial setting for controlling various chambers and sub-processors. The memory, or computer-readable medium, 142 of the CPU 140 may be one or more of readily available memory such as random access memory (RAM), read only memory (ROM), floppy disk, hard disk, or any other form of digital storage, local or remote. The support circuits 144 are coupled to the CPU 140 for supporting the processor in a conventional manner. These circuits include cache, power supplies, clock circuits, input/output circuitry and subsystems, and the like. In one embodiment, the memory 142 may store a software routine (e.g., metrology software 143).

In a basic etch operation, a substrate 114 is placed on the pedestal 112 and process gases are supplied from a gas panel 118 through one or more entry ports 116 and form a gaseous mixture 146. The gaseous mixture 146 is ignited into a plasma 148 in the chamber 102 by applying power from the plasma and bias sources 130 and 122 to the inductive coil element 138 and the cathode 112, respectively. Typically, the chamber wall 134 is coupled to an electrical ground 152, or other grounding provisions are made. The pressure within the interior of the chamber 102 is controlled using a throttle valve 150 and a vacuum pump 120. The temperature of the wall 134 is controlled using liquid-containing conduits (not shown) that run through the wall 134. Those skilled in the art will understand that other forms of etch chambers may be used to practice the invention, including chambers with remote plasma sources, microwave plasma chambers, electron cyclotron resonance (ECR) plasma chambers, capacitively coupled plasma chambers, and the like.

In order to obtain desired process measurements, the measuring tool 103 may be used by a computer 162 for etch depth and/or etch rate predictions before, during, and/or after an etch operation, as described below. The measuring tool 103 is capable of detecting the reflected electromagnetic radiation (e.g., light) by interferometry. In one embodiment, the measuring tool 103 detects a single wavelength of electromagnetic radiation. In other embodiments, the measuring tool 103 may detect a plurality of wavelengths of electromagnetic radiation with various intensities. In some aspects, detecting a plurality of wavelengths of electromagnetic radiation may be used advantageously, since the detected reflected electromagnetic radiation waves may behave differently for different wavelengths during a substrate process, such as an etch process.

Examples of possible electromagnetic radiation sources (broadband sources) might be a tungsten filament lamp, laser diode, xenon lamp, mercury arc lamp, metal halide lamp, carbon arc lamp, neon lamp, sulfur lamp or combination thereof. In one embodiment one or more light-emitting diodes (LEDs) can be used as a electromagnetic radiation source.

A suitable electromagnetic radiation may be a visible light, infrared light, UV light and the like. In one embodiment, electromagnetic radiation waves having wavelengths of between about 200 nm and about 1700 nm may be used to advantage, since electromagnetic radiation within these ranges may prevent any potential damages to the substrate surface. Depending on the material layer that is exposed to the electromagnetic radiation, a desired wavelength may be used such that the material layer may be transparent. For example, for a Ti Nitride layer, a wavelength of about 500 nm may be used in order for the Ti Nitride layer to be transparent. In another embodiment, when examining TEOS or silicon nitride layers, a shorter wavelength (e.g., 200 nm) may be used. In one embodiment, for a depth trench feature (a feature having a trench depth of about 7 microns to about 8 microns), a longer wavelength, for example a wavelength of about 700 nm to about 1500 nm may be desired.

The measuring tool 103 generally includes an optics assembly 104 coupled to an actuator assembly 105, an electromagnetic radiation source (e.g., light source 154), a spectrometer 156, and a computer 162. The computer 162 and controller 136 may be one and the same. However, in one embodiment, the controller 136 is used for controlling the measuring tool 103, while the computer 162 is used for data collection and analysis. The computer 162 may include a neural network module (e.g., neural network software 170). The neural network software 170 may include an executable program module, for example a Dynamic Link Library (DLL) that performs one or more neural network (e.g., a multilayer perceptron network) functions at runtime. The neural network software 170 may also be stored and/or executed by a second CPU (not shown) that is remotely located from the hardware being controlled by the CPU 140. In another embodiment, the neural network software 170 may be stored in controller 136. In yet another embodiment, the neural network software 170 may be located in both the controller 136 and the computer 162.

A spectrometer may be used to collect the radiation from a broadband light source, split the radiation into discrete wavelengths, and detect the intensity of the radiation at each discrete wavelength. The spectrometer may include an input slit, a diffraction grating (or optical prism), a diffraction grating controller and a detector array to collect the incoming radiation. In one embodiment the spectrometer, is used to scan across a range of wavelengths of the emitted radiation as a function of time to monitor and control the process. Suitable sensors used to measure the various wavelengths may include the following classes of sensors, for example, a photovoltaic, a photoconductive, a photoconductive-junction, a photoemissive diode, a photomultiplier tube, a thermopile, a bolometer, a pyroelectric sensor or other like detectors. When using sensors detectors of this type, it may be advantageous to use filters to limit desired wavelengths that are detected.

The actuator assembly 105 may include a movable stage assembly 106, such as an XY stage, and one or more motors 160 adapted to respond to commands from a controller 136 to move the optics assembly 104 to a desired location. It is contemplated that the movable stage assembly 106 may support multiple optics assemblies 104. In another embodiment, the optics and/or the stage assembly may be stationary. The optics assembly 104 generally includes passive optical components, such as a lens, mirrors, beam splitters, and the like and is disposed over a window 108 formed in the ceiling 110 of the chamber 102. The window 108 may be fabricated from quartz, sapphire, or any other material that is transparent to electromagnetic radiation produced by the light source 154. The optics assembly 104 guides and focuses electromagnetic radiation (e.g., light 166) provided by the light source 154 through the window 108 to form a spot of light which illuminates a specific region 168 of the substrate 114 disposed on the pedestal 112 directly below the window. The illuminated region 168 is generally a large enough area to cover the expected feature to be measured plus an allowance for the expected variation within the manufacturing tolerances. The spot of light may have diameter range of between about 1.0 millimeter to about 12 millimeters.

Light reflected from the illuminated region 168 of the substrate 114 is partially collected and guided by the optics assembly 104 to the spectrometer 156. The spectrometer 156 detects a broad spectrum of wavelengths of light, enabling features on the substrate 114 to be observed using a wavelength having a strong reflectance signal or using multiple wavelengths, thus improving the sensitivity and accuracy of the measuring tool 103. It is contemplated that, more generally, any analyzer capable of analyzing the reflected light and providing an output to the computer 162 may be utilized. It is further contemplated that, in another embodiment of the measuring tool 103, the spectrometer 156 may detect light reflected off of the substrate 114 from a source other than light source 154, such as from a heating lamp or other light source.

A light source 154 (e.g., broadband light source) is generally a source of light having a wavelength spectrum in the range of about 200 to about 800 nm. Such a broadband light source 154 may include for example, a mercury (Hg), xenon (Xe), or Hg—Xe lamp, a tungsten-halogen lamp, and the like. In one embodiment, the broadband light source is a xenon flash lamp. The xenon flash lamp is adapted to flash or pulse during a process. For example, the xenon flash lamp is adapted to turn off when a gaseous mixture is ignited into a plasma, and it is adapted to turn on when the spectrum is ready to be collected.

In one embodiment, the optical interface between the optics assembly 104, the light source 154, and the spectrometer 156 may be provided using a fiber-optic array 164. The fiber optic array 164 is generally a bundle of optical fibers in which some fibers (source fibers) are connected to the light source 154 and the remaining fibers (detector fibers) are connected to the spectrometer 156. In one embodiment, the fiber optic array 164 has a combined diameter of about 0.2 millimeters to about 1 millimeter. The focus of the light emanating from the source fibers of the fiber optic array 164 may be unfocused enough to allow the reflected light to be directed to all of the detector fibers connected to the spectrometer 156. The focus may be adjusted by varying the position of the end of the fiber optic array 164 either closer to or further from the optics assembly 104. The size of the fibers may also vary to assist in the collection of the reflected light. For example, the source fibers connected to the broadband light source 154 may have a diameter of about 100 microns and the detector fibers connected to the spectrometer 156 may have a diameter of about 300 microns. In another embodiment, the fiber optic array 164 may include a single source fiber or an array of source fibers coupled to the broadband light source 154 and passing through a beam splitter that directs the reflected light to the spectrometer 156 without the need for separate detector fibers. The focus in this embodiment may be much sharper since no detector fibers are required to direct the reflected light to the spectrometer 156.

Output from the spectrometer 156 is delivered to the computer 162 or to the controller 136 for analysis and may be used as learning data by a multilayer perceptron network as discussed further below. The computer 162 may be a general purpose computer or a special purpose computer and generally is configured with similar components as used by the controller 136 described above. The output from the computer 162 is delivered to the controller 136 so that process adjustments may be made if necessary. In another embodiment, the computer 162 and controller 136 may be the same device, containing all the required software and hardware components necessary to control the process and analyze the spectral information. In either case, the controller 136 or the computer 162 may be adapted to include a neural network platform (e.g., Multilayer perceptron network) for monitoring a process and in particular, for etch depth predictions as discussed below.

The controller 136 is further adapted to provide a signal to the motor 160 to move the XY stage assembly 106 and the optics assembly 104 to enable taking measurements over a larger area of the substrate 114. In one embodiment, the controller 136 is adapted to collect and/or record substrate state information in one area of the substrate and then move to another measurement site for in-situ monitoring of the substrate state during processing. In one embodiment of the invention, the total movement range of the XY stage assembly 106 encompasses at least the dimensions of one full die of a semiconductor substrate being processed, such that all of the positions of the die can be accessed for measurement. In one specific embodiment, the XY stage assembly 106 provides a range of motion in a square area of about 33 millimeters by about 33 millimeters.

In one exemplary embodiment, the in-situ metrology tool 103 may be the EyeD™ metrology module, available from Applied Materials of Santa Clara, Calif. As shown in FIG. 1, an EyeD™ chamber module may be comprised of two parts. One is an interferometric and/or spectrometric measurement assembly, which may be adapted for measuring the film thickness and/or the width of structures. The other is an optical electromagnetic emission (OES) monitor assembly to monitor the chamber plasma state.

The interferometric and/or spectrometric measurement assembly may be, for example, configured to perform an interferometric monitoring technique (e.g., counting interference fringes in the time domain, measuring position of the fringes in the frequency domain, and the like) to collect wavelength length intensities for a neural network structure (e.g., a multilayer perceptron network structure) in order to predict etch depth profile of the structures being formed on the substrate in real time.

Light reflected from the substrate 114 may be detected and/or collected by the optical assembly 104 in the form of light signals and the signals may be transmitted by a signal cable 164 to a spectrometer 59. The signals may be analyzed by the spectrometer 156 and the computer 162. In one embodiment, a neural network structure (e.g., a multilayer perceptron) may use such signals as input and output data and generate a model that is capable of etch rate or etch depth prediction for a substrate processing system. The analyzed results can be used to generate control commands that control the reactor chamber via controller 136 or computer 162. The assembly may be used to determine the endpoint of an etch process (interferometric endpoint” (IEP)). The assembly may also use one or more non-destructive optical measuring techniques, such as spectroscopy, scatterometry, reflectometry, and the like, to measure the width of structures.

Another EyeD™ chamber module is an optical electromagnetic emission (OES) monitor assembly, which may be used for monitoring the chamber plasma state. The OES monitor can be used to determine the degree of chamber matching and the source(s) of process and/or system fault. OES signals emitted from the plasma 148 are collected by a signal collecting device 155 and the signals are transmitted by a signal cable 186. The signals are analyzed by the spectrometer 156 and the computer 162. In one embodiment of the present invention, the signals may also be used by a neural network (e.g., a multilayer perceptron network) to generate a working model for etch depth predictions and then the working model may be used to generate control command in order to control the reactor chamber via controller 136.

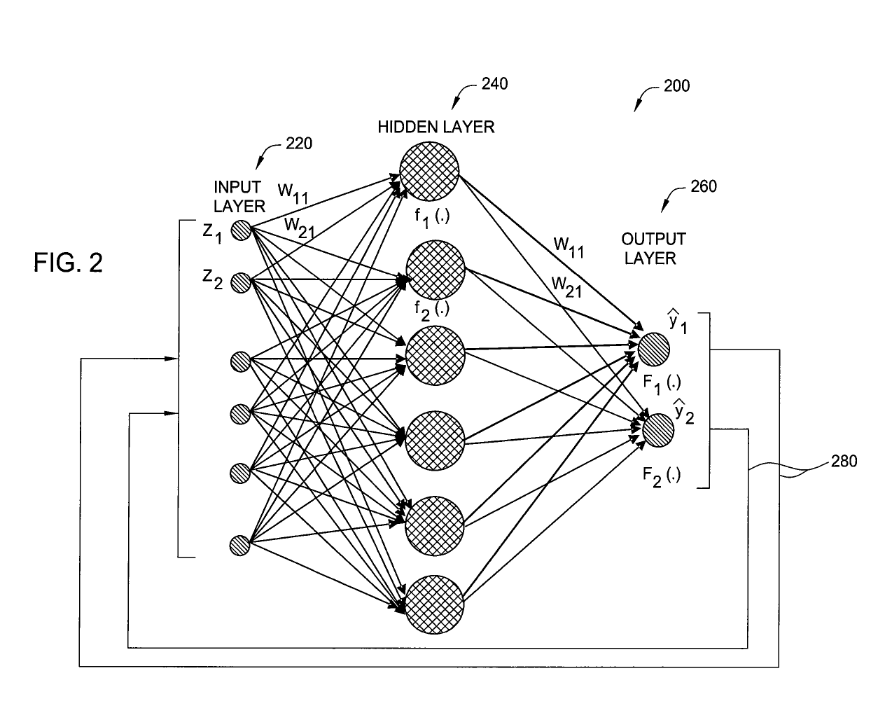

FIG. 2 illustrates a multilayer perceptron (MLP) network 200 according to one embodiment of the present invention. The MLP network 200 is a member of the neural network family, capable of computing one or more outputs from multiple inputs by forming a linear combination based on weights of the inputs, and/or utilizing one or more transfer functions (e.g., step functions and the like) and applying the linear combination of the inputs to the transfer functions in order to obtain one or more outputs. The MLP network 200 is an interconnected group of artificial neurons which may use a mathematical or computational model for information processing based on a connectionist approach to computation. In one embodiment, of the present invention, the MLP network 200 is capable of using one or more output data as input data. In one embodiment of the present invention, MLP network 200 may be stored as a software module in computer 162 (e.g., neural network software 170).

The MLP network 200 may include a set of source nodes forming an input layer 220, one or more hidden layers 240 of computation nodes, and one output layer 260. The input layer 220 may include a plurality of inputs (e.g., z₁, z₂, . . . z_{N}) and the output layer 260 may include one or more outputs (e.g., ŷ₁ and ŷ₂).

In one embodiment, the MLP network 200 is adapted for input signals to propagate through the network layer-by-layer, where a number of computations are performed. In one embodiment, the MLP network 200 may be a feed forward network. MLP network 200 is capable of approximating any continuous selected function to a desired accuracy. In one embodiment of the present invention, MLP network 200 is adapted for an environment where supervised learning is used. For example, a training set of input/output data (training data) may be provided to the MLP network 200 and then the MLP network 200 may learn to model a dependency between the training data. The MLP network 200 may associate an appropriate weight with each input and output data while operating in a supervised learning mode, and then it may incorporate weighting factors (e.g., w and W) into a model using a gradient-based algorithm or any other algorithm.

It is contemplated that training data may include one or more reflected signal spectrums, one or more optical waves, physical parameters, such as mask related data, film material information, the measured value of the parameter that is intended for prediction (e.g., etch depth, material layer thickness, critical dimensions, and others) and other substrate related information. It is also contemplated that during the training process, active training may be utilized as new data becomes available.

In one embodiment of the present invention, the training data with allocated weighting factors is used for a modeling process. Then a substrate processing technique (e.g., etch) may be repeated to establish a model in order to obtain a set of optimum weighting factors. In one embodiment of the present invention, the weights (e.g., w and W matrices) are adjustable parameters of the MLP network 200 and they are determined through the training process. The optimal weights are generally determined by an iterative minimization scheme during the model generation phase. In one embodiment, the MLP network 200 is adapted to use an output feedback to improve the stability of the system and increase the convergence rate during the training and model of a multi-input, single output (MISO) system by using an auto-regressive exogenous process and the like.

In one embodiment of the present invention, MLP network 200 is capable of modeling complicated non-linear relationships between a number of parameters related to a physical system by using one or more feedback loops 280, containing past and present output data, into the input layer. In this way, the system may increase the convergence and overall accuracy. In one embodiment, the MLP network 200 may incorporate physical constraints into model estimation/prediction in order to reduce the error frequency. In addition, the MLP network 200 may continuously operate in real time, instead of a spectral domain, and provide the global system (for example, substrate processing system 100) with data predictions (e.g., etch depth and material layer thickness) in a short time (e.g., 5 seconds or less time).

The MLP network 200 may establish a model that can be used to predict etch depth of a feature on a substrate. For example, by utilizing substrate state information derived from a reflectance signal collected at a designated area of a substrate under process in addition to other related data, MLP network 200 may learn a relationship between such data and based on the relationship established, the model can be used to predict etch depth for a substrate in a substrate processing system.

Although some embodiments of the substrate processing system 100 are described with reference to etch depth prediction, it is contemplated that the present invention may be utilized to monitor substrate processing, for example, it may be used for prediction of material layer (e.g., film layer) thickness, critical dimensions and other parameters. It is also contemplated that the present invention may be utilized in fault detection techniques to ensure a stable process. For example, in one embodiment, the neural network may be adapted to monitor a process within a system and be based on a neural network model, and the system may generate an alert when a limit is exceeded than a typical data.

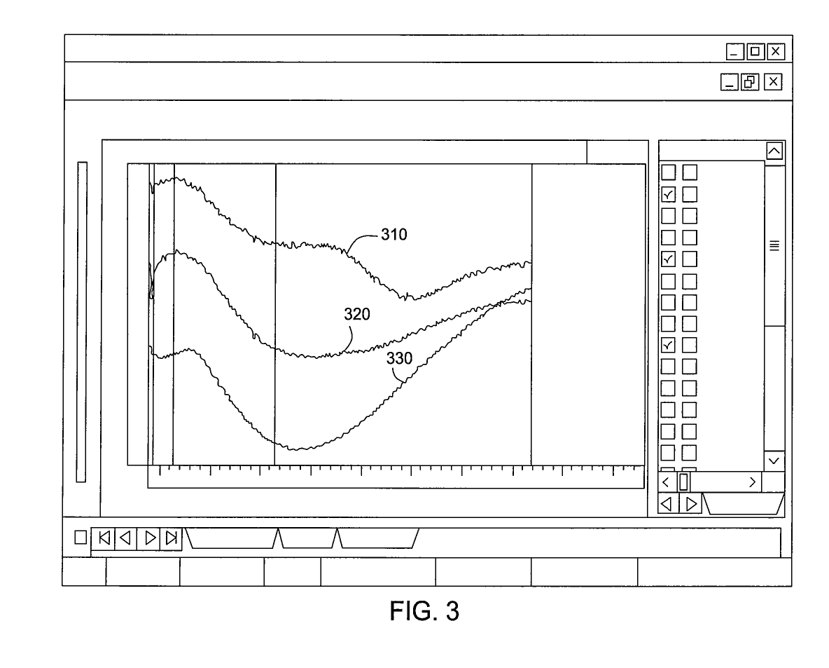

FIG. 3 illustrates a plurality of different wavelengths illustrating changes in the spectral intensity of radiation reflected from a feature on a substrate during an etch process. In one embodiment, a first portion of the collected spectrum (e.g., for example, wavelength 310) may be more sensitive to mask erosion. On the other hand, for example, a second and a third portion of the collected spectrum (e.g., wavelengths 320 and 330) may be more sensitive to etch depth variations. Therefore, in one embodiment of the present invention, the neural network software 170 is adapted to collect a plurality of wavelengths associated with different intensities in order to generate an MLP network model.

In one embodiment of the present invention, a measuring tool may be used to perform spectral analysis after an etch operation. The measuring tool may detect a broad spectrum of reflected light from a substrate surface, having a feature (e.g., a film layer or a trench) and then analyze all or a portion of the reflectance signal using various analyses, such as interferometry or spectrometry and other techniques. In one embodiment, the collected data may include one or more wavelengths with associated intensities. Then, the feature of the substrate may be measured using a measuring system. In addition, a number of etch operations may be performed while a measuring tool detects a broad spectrum of the reflected light from the surface of the substrate. Thereafter, a number of wavelengths with respective intensities may be collected, where each group of wavelengths may be associated with a certain etch depth. The collected measurements may be used as learning data for the MLP network 200. The MLP network 200 may utilize the learning data and model a relationship between a particular wave spectrum (e.g., optical signal intensity) and etch depths of a substrate feature.

In one embodiment, the training data may include a data set that has been collected on a number of substrates. For example, using an interferometer, while a substrate is being etched, a plurality of wavelengths are detected for each data point within a time spectrum and are provided to the MLP network 200 in order to provide a model based on a relationship between the input (e.g., wavelength intensities reflected from the substrate) and the outputs (e.g., associated etch depth). In one embodiment, the MLP network 200 may be adapted to take other related process data, such as pre-etched and post-etched depth measurement of structures being formed on the substrate, critical dimension measurement (e.g., substrate state information) and other related data for training. While some data collection are performed in-situ using a dynamic optical measuring tool capable of taking measurements at various small, designated locations on a substrate, other related data may be collected ex-situ and used in combination with the in-situ data by the MLP network 200 in order to generate a model. Based on the input data and its corresponding output data, the MLP network 200 may process the learning data and learn from previous input data and generate a working model and make improved etch depth predictions during an etch process. In one embodiment, the data collection for training may be repeated on one or more substrates.

The MLP network 200 may modify the value of the weighting factors based on the sensitivity that each input provides to the model. For example, in one embodiment, some input wavelength intensities may provide more sensitivity to the MLP network modeling, thus, they will have higher weighting factors, and on the other hand, other input wavelengths may provide less sensitivity to the MLP network modeling and thus, they may have lower weighting factors. In some embodiments, the feedback loop 280 may provide an output data (e.g., as future input data), as learning data to MLP network 200) in order to improve the prediction results. At the end of the learning process, a final set of weighting factors are then associated with a model. In one embodiment of the present invention, the model may include a series of matrices of weighting factors for inputs and outputs and it may be used to control the operation of a substrate processing system (e.g., substrate processing system 100) by predicting real time etch depths, critical dimension size and the like during an etch process.

In one embodiment of the present invention, the MLP network 200 is adapted to predict a current depth in 0.5 seconds or less. In another embodiment, the MLP network 200 is adapted to predict a current depth in 0.1 seconds or less time.

In one embodiment of the present invention, the MLP network 200 is capable of predicting feature depth of a structure on a substrate within a desired range. For example, in one embodiment, a standard deviation of 2.75 nm was calculated when comparing actual depth of a structure with a predicted depth of the structure.

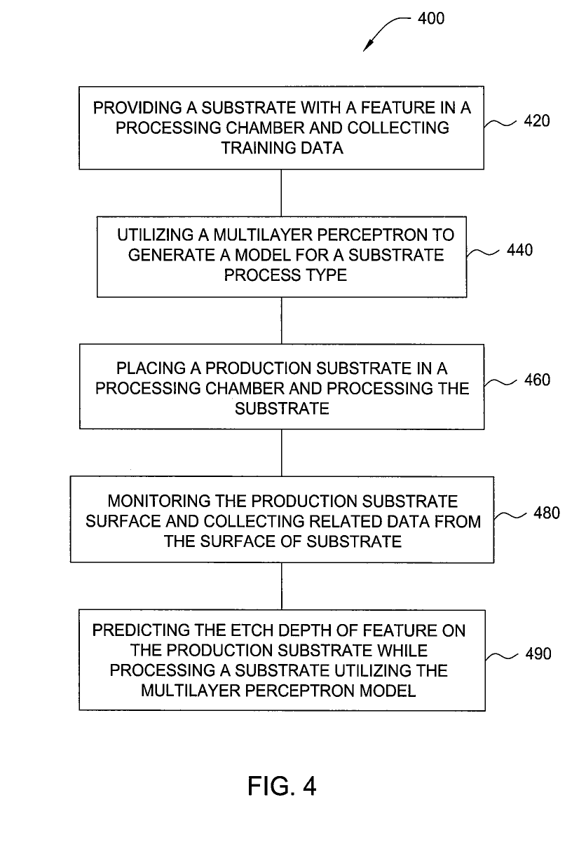

FIG. 4 illustrates operations 400 according to an implementation of the present invention. The operations of 400 may be performed, for example, by the controller 136. Moreover, various steps in the methods set forth below need not be performed or repeated on the same controller 136. In addition, the operations 400 may be understood with occasional reference to FIGS. 1, 2 and 5A-C.

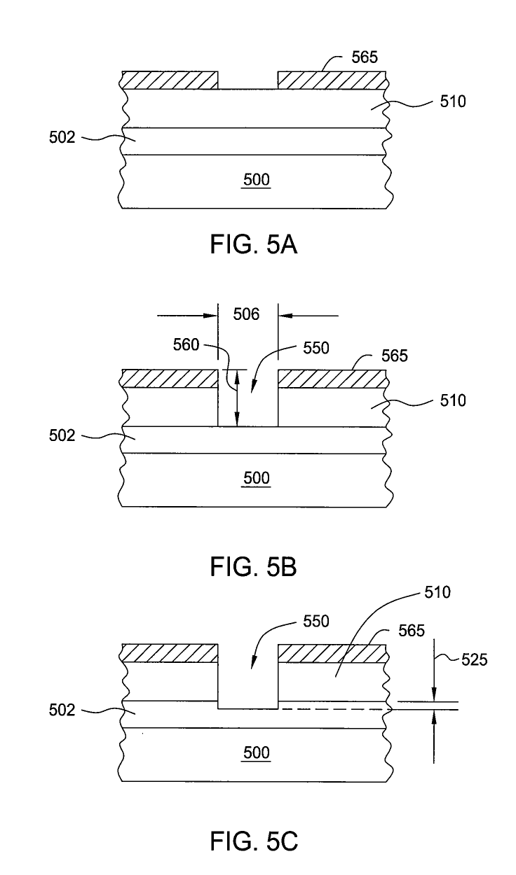

FIGS. 5A, 5B, and 5C illustrate schematic, cross-sectional views of a portion of a substrate (e.g., 65 nm process) having a feature being etched in material layer and using the operations of 400 to predict the etch depth of the structure 550. FIG. 5A, illustrates a substrate 500 before an etch process. The substrate 500 may include a first material layer 502, a second material layer 510. The second material layer, may include a resist layer 565 on certain portions of the layer. FIG. 4B illustrates, the structure 550 after a first etch process, having an etch depth 560 and FIG. 4C illustrates the structure 550, having an etch depth 465, after a second etch process.

The operations begin, at step 420, where a substrate 500 is introduced to the substrate processing system. For convenience, herein the same schematic, cross-sectional views and respective reference numeral may relate to either a test or a product substrate 500.

At Step 420, a number of training data may be collected by a measuring device while the substrate 500 may be processed (e.g., etched). For example, a number of structures, such as structure 550, may be inspected and etch depth 560 and dimensions of the structure 550 may be measured before, during and after an etch process. At this step, the optics assembly guides and focuses an electromagnetic radiation wave (e.g., light 166) provided by the light source 154 forming a spot of light which illuminates a substrate, while the measuring tool detects the reflected electromagnetic radiation (e.g., light) by interferometry for use as training data. In one embodiment, the measured dimensions may include critical dimensions (e.g., the width 506 of the structure) as well as thickness of the layer 510 being etched. Such measurements may be performed using a metrology tool ex-situ with respect to the etch process. In one exemplary embodiment, optical measurement tool is the TRANSFORMA™ metrology module of the CENTURA® processing system, available from Applied Materials of Santa Clara, Calif. The TRANSFORMA™ metrology module may use one or more non-destructive optical measuring techniques, such as spectroscopy, interferometry, scatterometry, reflectometry, ellipsometry, and the like. The measured parameters include topographic dimensions and profiles of the structures fabricated on substrates, as well as a thickness of either patterned or blanket dielectric and conductive films. Measurements of critical dimensions for the structures 550 are typically performed in a plurality of regions of the substrate 500, such as a statistically significant number of the regions (e.g., 5 to 9 or more regions), and then averaged for such a substrate. Optionally, the step 420 may be repeated and the substrate 500 may be etched to a second etch depth 565, as shown in FIG. 5C, while training data is collected. The second etch depth may be deeper than the first etch depth by a depth 565.

At step 440, the MLP network 200 may use the collected data (e.g., etch depth, dimensions of the structure 550 and etc.) as training data and establish a model that can be used to predict etch depth of a feature on a substrate. For example, by utilizing substrate state information derived from a reflected signals collected at a designated area (e.g, structure 550) of a substrate under process, in addition to other related data (e.g., critical dimensions and material thickness, material type and others), the MLP network 200 may learn a relationship based on the reflected signals and the etch depth.

At step 460, a production substrate may be placed in processing system 100. At step 480, a plasma etch process may start while the surface of the substrate 500 may be monitored using an inspection device, for example an in-situ metrology tool 103. For example, the in-situ measuring tool may detect a broad spectrum of reflected light. The measuring tool 103 is capable of detecting a broad spectrum of reflected light and analyzing all or portions of the reflectance signal using various analyses, such as interferometry or spectrometry, amongst others.

At step 490, the detected spectrum may be used as inputs for the MLP network 200. Then, the MLP network 200 may predict the etch depth promptly (e.g., within 1/10 of a second) using the model generated at step 440. The production substrate may etch continuously for a specified duration of time period, while the model may predict the etch depth periodically. In one embodiment, the computer 162 may be adapted to depict the etch depth prediction on a computer screen or write to a file and/or store to a hard disk located in the computer 162 or in the controller 138. In addition, the training data collected at step 420 may be used to predict other depths above and beyond the depth reached at step 420.

By using a neural network model adapted to predict etch depth of a feature on a semiconductor substrate based a set of learning data (e.g., optical signal intensity, film thickness, and other physical parameters), the system may dynamically estimate the etch depth within a desired range (in terms of error standard deviation) with high computational speed in real time.

Although the embodiments disclosed above, which incorporate the teachings of the present invention, have been shown and described in detail herein, those skilled in the art can readily devise other varied embodiments which still incorporate the teachings and do not depart from the spirit of the invention.

1. A method for monitoring film thickness of a substrate in a substrate processing system, comprising:
monitoring a first set of reflected electromagnetic radiation from an electromagnetic radiation source during processing of a first set of one or more substrates;
associating the first set of reflected electromagnetic radiation to a film thickness profile of the first set of one or more substrates to form a first set of training data;
monitoring a second set of reflected electromagnetic radiation from the electromagnetic radiation source during processing of a second set of one or more substrates; and
using the first set of training data to predict a film thickness profile of the second set of one or more substrates during processing of the second set of one or more substrates.

2. The method of claim 1, further comprising:
associating the second set of reflected electromagnetic radiation to the film thickness profile of the second set of one or more substrates to form a second set of training data;
monitoring a third set of reflected electromagnetic radiation from the electromagnetic radiation during processing of a third set of one or more substrates; and
using the first set of training data and the second set of training data to predict a film thickness profile of the third set of one or more substrates during processing of the third set of one or more substrates.

3. The method of claim 1, wherein an electromagnetic radiation source provides electromagnetic radiation having a wavelength between about 200 nm and about 1700 nm.

4. The method of claim 1, wherein the electromagnetic radiation source provides a plurality of electromagnetic radiation having different wavelengths.

5. The method of claim 1, wherein the monitoring is performed using optical metrology and a neural network.

6. The method of claim 5, wherein the optical metrology comprises one or more techniques selected from the group consisting of interferometry, scatterometry and reflectometry.

7. The method of claim 5, wherein the neural network is a multilayer perceptron network.

8. Apparatus for obtaining in-situ data regarding processing of a substrate in a substrate processing chamber, comprising:
a data collecting assembly for acquiring training data related to a substrate disposed in a processing chamber;
an electromagnetic radiation source;
at least one in-situ metrology module to provide measurement data; and
a computer, wherein the computer includes a neural network software, wherein the neural network software is adapted to model a relationship between the plurality of the training and other data related to substrate processing.

9. The apparatus of claim 8, wherein the data collecting assembly further comprises at least one metrology adapted for non-destructive optical measuring technique.

10. The apparatus of claim 8, wherein the data collecting assembly further comprises electromagnetic radiation source for providing one or more radiation wavelengths on to the substrate.

11. The apparatus of claim 8, wherein the electromagnetic radiation source is a light source.

12. The apparatus of claim 9, wherein the neural network software is adapted to predict the etch depth of a feature on the substrate.

13. The apparatus of claim 9, wherein the neural network software is adapted to predict a critical dimension of a feature on the substrate.

14. The apparatus of claim 9, wherein the neural network software is adapted to predict a film thickness formed on the substrate.

15. A method for monitoring an etch depth profile of a substrate feature in a substrate processing system, comprising:
monitoring a first set of reflected electromagnetic radiation from an electromagnetic radiation source during processing of a first set of one or more substrates;
associating the first set of reflected electromagnetic radiation to an etch depth profile of the first set of one or more substrates to form a first set of training data, wherein the associating the first set of reflected electromagnetic radiation is perform by a neural network software;
monitoring a second set of reflected electromagnetic radiation from the electromagnetic radiation source during processing of a second set of one or more substrates; and
using the first set of training data to predict an etch depth of the second set of one or more substrates during processing of the second set of one or more substrates.

16. The method of claim 15, further comprising:
associating the second set of reflected electromagnetic radiation to the etch depth of the second set of one or more substrates to form a second set of training data;
monitoring a third set of reflected electromagnetic radiation from the electromagnetic radiation during processing of a third set of one or more substrates; and
using the first set of training data and the second set of training data to predict an etch depth of the third set of one or more substrates during processing of the third set of one or more substrates.

17. The method of claim 15, wherein an electromagnetic radiation source provides electromagnetic radiation having a wavelength between about 200 nm and about 1700 nm.

18. The method of claim 15, wherein the electromagnetic radiation source provides a plurality of electromagnetic radiation having different wavelengths.

19. The method of claim 15, wherein the optical metrology comprises one or more techniques selected from the group consisting of interferometry, scatterometry and reflectometry.

20. The method of claim 15, wherein the neural network is a multilayer perceptron network.
